(19) United States
(12) Patent Application Publication
(10) Pub. No.: US 2010/0093545 A1
(43) Pub. Date: Apr. 15, 2010

(54) METHOD FOR MAKING HIGH JC SUPERCONDUCTING FILMS AND POLYMER-NITRATE SOLUTIONS USED THEREFORE

(75) Inventors: Michael J. Cima, Winchester, MA (US); Masateru Yoshizumi, Watertown, MA (US); Daniel E. Wesolowski, Cambridge, MA (US); Yoda R. Patta, Cambridge, MA (US)

Correspondence Address: CHOATE, HALL & STEWART LLP, TWO INTERNATIONAL PLACE, BOSTON, MA, 02110, US

(73) Assignee: MASSACHUSETTS INSTITUTE OF TECHNOLOGY, Cambridge, MA (US)

(21) Appl. No.: 12/306,415

(22) PCT Filed: Jun. 29, 2007
(86) PCT No.: PCT/US2007/072458

§ 371 Date: Dec. 22, 2009

Related U.S. Application Data
(60) Provisional application No. 60/831,426, filed on Jul. 17, 2006.

(51) Int. Cl. H01L 39/24; H01L 39/12

(52) U.S. Cl. 505/122; 505/470; 427/62; 252/500

(57) ABSTRACT

100-800 nm ReBCO films with critical current density (J_{c}) values in excess of 1 MA/cm² were fabricated from aqueous nitrate precursor solutions with additives. Additives such as polyethylene glycol (PEG) and sucrose were selected to suppress crystallization of barium nitrate. This produces higher concentration solutions resulting in thicker crack-free single layers. Additional water-soluble viscosity modifiers, such as polyvinyl alcohol (PVA) or cellulose-derivatives, were used to increase thickness and allow wetting of ceramic surfaces. Water vapor present at higher temperatures during heat-treatment damaged the films, while the role of water vapor at lower temperatures is still under investigation.

This application claims priority to provisional application Ser. No. 60/831,426 filed Jul. 17, 2006, the contents of which are incorporated herein by reference.

### BACKGROUND OF THE INVENTION

This invention relates to methods that use polymer-nitrate solutions to make high critical current density, high temperature superconducting films and also relates to the solutions themselves.

MOD (metal-organic deposition) is a proven technique for the production of YBCO superconducting films such as Y₁Ba₂Cu₃O_{7-δ} and is used in pilot scale production today (8). Numbers in parentheses refer to the references appended hereto, the contents of which are incorporated herein by reference. The most common fabrication route employs a mixture of metal trifluoroacetates (TFA) in a solvent that is coated on a textured and buffered metal substrate. The TFA-MOD process has proven quite successful in producing high quality YBCO films. Solution deposition quickly creates green films of reasonable thickness (˜1 μm) and optimized heat treatments have been developed that produce high performance films over several hundred meter lengths.

The presence of fluorine is both problematic and integral to the TFA-MOD process. BaCO₃ forms readily from most Ba compounds in the presence of CO₂ (in air, for instance). BaF₂, however, is stable against BaCO₃ formation and forms during the decomposition of barium trifluoroacetate (Ba(CF₃COO)₂). BaF₂ can then be removed and YBCO formed during high temperature annealing in the presence of flowing water vapor. The stability of BaF₂ is problematic from the viewpoint of industrial scale production. Removal of fluorine limits the growth of the YBCO layer, so uniform gas flow and P(HF) must be maintained across the sample to produce even, quality films. Complex reactor designs are therefore necessary to optimally remove HF gas from the system. This may limit the width of tapes that can be processed. The HF reaction product is also expensive to remediate.

Non-fluorine based MOD methods are therefore still of interest, despite the BaCO₃ formation problem. A number of non-fluorine based processes have demonstrated high performance (>1 MA/cm²). Kumagai and co-workers have produced ˜200 nm films with J_{c} values in excess of 4 MA/cm² on single crystal substrates (12). ORNL has found a Ba(OH)₂ and Y and Cu trimethylacetate (TMA) based route which also has produced thin (˜100 nm) films of >1 MA/cm² (9, 17, 18). Lu and co-workers at the University of Wisconsin produced 0.9 μm (Y,Sm)BCO films on rolling assisted biaxially textured (RABiTS) substrates with J_{c} up to 1.7 MA/cm². They used acetylacetonates dissolved in a mixture of pyridine and propionic acid (19). These non-fluorine MOD routes have apparently solved the BaCO₃ formation problem, but have some drawbacks. The precursor components are toxic and/or dangerous. Solution preparation schemes can be complex, often requiring multiple drying and re-dissolving steps. Film layer thicknesses per deposition are quite thin because of the result of poor solubility of Ba. The acetylacetonate process, for instance, required fifteen coatings to obtain the desired thickness. The TMA conversion heat treatment is quite complex and requires high water vapor pressure, which complicates reactor design.

Several researchers have turned to metal-nitrate solutions to create simpler and safer non-fluorine based deposition techniques. Many nitrates dissolve very easily in a large number of solvents, including ones of low toxicity and low cost such as water and methanol. NOₓ is produced during processing, but remediation is simple and inexpensive. However, nitrate solutions pose several problems for film production, including the hydroscopic nature of the reagents, the necessity of decomposing nitrates from the film during heat treatment, and difficulty in getting the solution to wet the oxide or oxide-coated metal substrate (14).

One solution to the substrate wetting problem is to spray the nitrate solution onto a heated substrate. Gupta et. al. obtained ˜1-3 micron YBCO films on YSZ substrates with J_{c}=42 A/cm² at 77 K using a process in which an all-nitrate solution was sprayed onto a heated (˜180° C.) substrate and subsequently heated to ˜900-950° C. under flowing oxygen (4). This process was refined by Supardi et al. They produced ˜2 micron films with J_{c}˜1.4 MA/cm² at 77 K by spraying an all-nitrate solution onto heated (˜850° C.) single-crystal STO substrates, followed by annealing at that temperature for 120 minutes (11). These processes, however, are more complex than the web-coating process used to apply TFA solutions. A more industry compatible process was developed by Apetrii et al. They produced 250 nm YBCO films on single crystal SrTiO₃ (STO) substrates with J_{c} values of 1 MA/cm² at 77 K using a polyacrylic acid-nitrate precursor solution in dimethylformamide. Their films were first heated at 170° C. for 3 hours before being placed into the furnace for high-temperature annealing at 775° C. (1). A number of other reports have fabricated other metal oxide films from nitrate-based solution (5, 10, 13, 14). These authors all chose to use organic solvents as the solution vehicle. The reasons for this consist of increased solubility of the polymer and improved wetting, while still maintaining adequate solubility of the cations. Jia et al (21) reported on polymer-assisted deposition of films, in which aqueous solutions of nitrates, polyethyleneimine (PEI), and ethylenediamine tetraacetic acid (EDTA) were discussed. This work produced crystalline YBCO, but no critical current densities were reported.

### SUMMARY OF THE INVENTION

The method for making superconducting films according to one aspect of the invention includes dissolving nitrate precursor compounds containing cations of a superconductor in water to form a solution. Polymers and other additives are added to the solution and the solution is coated on a substrate. The coating is then heat treated to form a superconducting film. In a preferred embodiment, a viscosity modifier and crystallization inhibitors are added to the solution. It is preferred that the heat treatment include decomposition and high-temperature annealing segments. It is also preferred that the coating step comprise spin coating or slot coating. It is preferred that the temperature of the solution during spin coating be at room temperature or an elevated temperature (between 70-90° C.). A suitable temperature for the decomposition segment is in the range of 100° C. to 650° C. The high-temperature annealing segment is preferably performed in a temperature range of 725° C. to 820° C.

A preferred viscosity modifier is polyvinyl alcohol (PVA), methyl cellulose (MC), hydroxyethyl cellulose (HEC), or hydroxypropyl methyl cellulose (HPMC). Preferred crystallization inhibitors are polyethylene glycol (PEG) and sucrose. Other embodiments may include amines or other polyethers, but not carboxylic acids (such as EDTA or citric acid).

A suitable superconductor is ReBCO wherein Re is a rare earth such as yttrium or holmium. The ReBCO may have a Re:Ba:Cu stoichiometry of approximately 1:1.8:3.

It is preferred that the substrate be a single crystal of a material such as LaAlO₃ (LAO). Other embodiments may include buffered metal substrates such as those prepared either by the RABiTS or the IBAD buffered metal substrates (6).

In some embodiments, water vapor is present during the heat treatment process.

In another aspect, the invention is a polymer-nitrate solution including nitrate compounds including Re, Ba, and Cu cations; a viscosity modifier; and a crystallization inhibitor all dissolved in water. This solution may be used to make high critical current density, high-temperature superconducting thin films.

The conventional wisdom is that one should use polymers that decompose easily. Surprisingly, we find that polymers that decompose over a range of 200° C. to 600° C. yield better results. We have discovered that addition of crystallization inhibitors to the formulation dramatically reduces segregation during processing. It is surprising that these additives also reduce delamination during early stages of decomposition.

The selection of polymer or other additive depends on its intended role in the solution. A solution additive may be used as a viscosity modifier or a crystallization inhibitor. The role of the viscosity modifier is to increase the viscosity of the solution and help the solution wet the substrate upon spin-coating. The crystallization inhibitor acts to prevent segregation of any of the components (especially Ba(NO₃)₂) during processing of the film. The overall concentration of the solution can thus be greatly increased without risking precipitation of the nitrates. All of the additives must be soluble in water, and stable in the solution over long periods of time.

### BRIEF DESCRIPTION OF THE DRAWINGS

FIG. 1 is a graph of a typical heat treatment profile for non-fluorine nitrate based films.

FIG. 2 shows solution viscosity vs. green and final film thicknesses for PVA-nitrate based films.

FIGS. 3(a) and 3(b) are TGA profiles of polyvinyl alcohol (PVA) (a) and PVA-nitrate film (b).

FIGS. 4(a) and 4(b) are TGA profiles of methyl cellulose (MC) (a)and MC-nitrate film (b).

FIGS. 5(a) and 5(b) are TGA profiles of polyacrylic acid (PAA) (a) and PAA-nitrate film (b).

FIG. 6 is a photomicrograph showing large dendritic structures in films based on solutions without crystallization inhibitors.

FIG. 7. is an x-ray diffraction pattern of segregated nitrate-based film showing Ba(NO₃)₂ presence.

FIG. 8 is a photomicrograph of a 600 nm YBCO film, showing no cracking or segregation.

FIG. 9 is an x-ray diffraction pattern for YBCO film with J_{c}=3.73 MA/cm².

FIG. 10 is an x-ray diffraction pattern for HoBCO film with J_{c}=1.79 MA/cm².

FIG. 11 is an x-ray diffraction pattern for YBCO film on CeO₂-capped YSZ substrate showing BaCeO₃ formation.

### DESCRIPTION OF THE PREFERRED EMBODIMENT

### Experimental Procedure

All of the variants of the polymer-nitrate precursor solutions involved yttrium nitrate hexahydrate (Y(NO₃)₃.6H₂O, MW 382.94 g) or holmium nitrate pentahydrate (Ho(NO₃)₃.5H₂O, MW 440.93 g), copper nitrate trihydrate (Cu(NO₃)₂.3H₂O, MW 241.57 g), and barium nitrate (Ba(NO₃)₂, MW 261.35 g) dissolved in deionized water, making a light blue solution with 0.3-0.8 M total cation concentration. The stoichiometric ratios of the Y,Ba,and Cu (BYC) and Ho,Ba, and Cu (HBC) solutions were RE:Ba:Cu=1:1.8:3, where RE is the rare earth cation Y or Ho.

The first variant of the polymer-nitrate solution involved the addition of polyvinyl alcohol (PVA, MW 15000) to an aqueous solution of all the nitrates under heat and stirring. Approximately 5-10 wt % PVA with respect to the total weight of the nitrate-water solution (˜63-125 wt % with respect to the total nitrates, depending on the solution concentration) was added before the solution reached 40° C., resulting in a cloudy light blue solution. The cloudy solution became clear at around 80° C., after which the solution was taken off of the hot plate to cool. Polyethylene glycol (PEG) was added to some solutions. 5-20 wt % PEG with respect to the total weight of the PVA was added to PVA-nitrate solutions under moderate heating and stirring. The finished precursor solution was a viscous, clear light blue solution in all cases.

The second variant of the polymer-nitrate solution involved addition of water to a mixture of approximately 2-4 wt % PEG and 0.6-1.8 wt % (with respect to the water) hydroxyethyl cellulose (HEC) and stirring under low heat (between 40 and 50° C.). More PEG was added after approximately 10-20 minutes to a total of 10-35 wt % with respect to the water. The nitrates were then added to the solution while it was stirred under low heat, in the order of barium nitrate, yttrium nitrate hexahydrate (in the case of BYC) or holmium nitrate pentahydrate (in the case of HBC), and copper nitrate trihydrate. Finally, between 10-35 wt % of sucrose was added to the solution, after which the heat was increased to approximately 80-95° C. In a version involving less total additive content, the solution was kept at an elevated temperature of between 70 and 85° C. in order to keep all of the components dissolved. When not in use the solution was kept at room temperature, which resulted in barium nitrate precipitates that re-dissolved upon heating. Use of larger amounts of additives allowed the solution to be stable at room temperature without barium nitrate precipitation. The concentrations of these solutions were generally higher than that of the PVA-nitrate variant, between 0.6 and 0.8 M total cation concentration.

Tests were done using a number of different solvents with varying degrees of solubility of the nitrates and/or additives, including acetone, methyl ethyl ketone (MEK), dimethylformamide (DMF), and propionic acid. A number of other viscosity modifiers were also tried, including cellulose derivatives such as hydroxypropyl methyl cellulose (HPMC) and methyl cellulose (MC), poly(acrylic acid) (PAA), and poly(methyl methacrylate) (PMMA). Crystallization inhibitors tested included glucose, fructose, ethylene glycol, diethylene glycol, ethylenediamine tetraacetic acid (EDTA), citric acid, glycerol, and urea. Polyethylene imine (PEI) was considered as a combination crystallization inhibitor and viscosity modifier. It was found that carboxylic acid ligands, such as citric acid and EDTA, produce poor superconducting layers. This is likely due to residue problems described by other authors (20).

Spin coating was done under ambient conditions on a single crystal LaAlO₃ (LAO) substrate with dimensions 10 mm×10 mm. Several drops of the precursor solution were placed on the surface of the substrate, which was then spun at a rate of 4000 rpm for 60-120 seconds and an acceleration time of 3 seconds. Coating was performed under dry conditions (dew point <0° C.) to further prevent Ba(NO₃)₂ crystallization in the coatings. Bridges were scribed into the as-spun film using a razor blade before the film was heat-treated.

Heat treatments were performed in a quartz tube furnace, with humidity, dew point, sample temperature, and P(O₂) recorded for each heat treatment run. The sample temperature was measured 1 cm away from the samples in the furnace, humidity and dew point were measured at the inlet to the furnace, and the P(O₂) was measured at the outlet of the furnace.

The sample heat treatments (FIG. 1) consisted of decomposition and high-temperature annealing segments. These segments were performed in either a single furnace run or separated into two furnace runs. The decomposition segment consisted of a 2° C./min to 10° C./min ramp to temperatures between 300° C. and 650° C. The high temperature annealing involved a ramp of up to 25° C./min to temperatures between 725° C. and 820° C. and annealing at that temperature for 88 minutes. The sample was then cooled down at a rate of approximately 2.5° C./min to 525° C., followed by a switch to dry oxygen and furnace cooling to room temperature.

One atmosphere total pressure gas was used throughout the heat treatment. Some heat treatments used dry 100 ppm O₂/balance N₂ gas throughout the decomposition and high-temperature annealing segments. Moist 100 ppm O₂/balance N₂ gas, with P(H₂O) between 24 Torr and 42 Torr, was used at the start of some furnace runs. A switch to pure oxygen was made at 525° C. during cooling to room temperature. The gas flow rate throughout the run was 4 SLM through a 53 mm diameter quartz tube.

Several parameters were varied experimentally. The ramp rate during the decomposition segment was varied between 2° C./min and 10° C./min. The ramp rate after 400° C. was varied between 10 and 25° C./min. The temperature at which the switch from moist to dry 100 ppm oxygen gas was made was varied between 100° C. and 400° C. The dew point of the water was varied between 23° C. and 36° C. The annealing temperature was varied between 725° C. and 800° C. The partial pressure of oxygen was varied between 50 ppm and 200 ppm O₂.

Characterization and testing were done on different aspects of the solution and the fired films. Inductively coupled plasma (ICP) was used to analyze the stoichiometries of the solutions and spin-coated films. Thermogravimetric (TGA) analysis was used to analyze the different polymers tried in the solutions. Differing amounts of additives were tested using optical microscopy for wetting and crystallization inhibiting characteristics. The thicknesses of the fired films were measured using a Tencor P10 profilometer. X-ray diffraction (XRD) was done using a three-circle diffractometer with a rotating anode source at 60 kV and 300 mA. Secondary electron and backscattered electron scanning electron microscopy (SEM) was performed on some samples. J_{c} tests were performed using a four-point current-voltage test following thermal evaporation of silver contacts and an annealing at 450° C. under oxygen. All J_{c} tests were performed at 77K in self-field. T_{c} measurements were performed using a DC superconducting quantum interference device (SQUID). Samples were zero-field cooled and their T_{c} measured upon warming from 20K to 100K in an applied field of 1-10 Oe.

### Results and Discussion

High-J_{c} YBCO and HoBCO films were reproducibly produced from several polymer-nitrate solutions. T_{c} was determined from SQUID measurements to be 90.5K for YBCO films. There is a wide range of processing conditions under which high performance films were obtained. More experiments are being done to determine the optimal combination of solution characteristics and heat treatment profiles and conditions in order to obtain the highest performances.

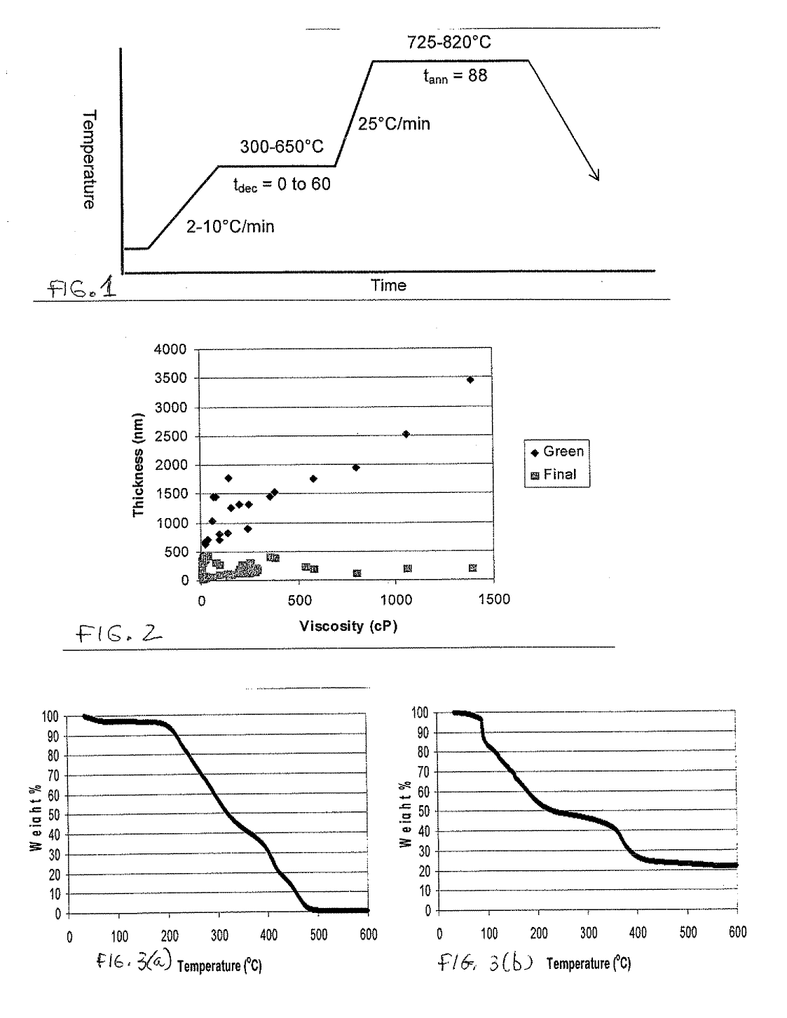

Film thicknesses ranged from under 100 nm to about 800 nm for a single layer. Films made from the PVA-nitrate solution were in general thinner than those made from the HEC-nitrate solutions. Solutions with higher cation concentrations yielded higher thickness films. The green film thickness of films made from PVA-nitrate solutions increased with increased viscosity, which was increased through increased PVA content. However, there was a limit to the final film thickness, which suggested that higher cation concentrations are required. FIG. 2 shows the changes in green and final film thicknesses with solution viscosity for PVA-nitrate based films. The thickness of a single layer of a HEC-nitrate based film was shown to reach ˜800 nm, and could potentially be higher. Addition of small amounts of HEC significantly increased the viscosity of the solution, which could further increase the final thickness of the film. Multiple layers of films based on either solution variant had higher thicknesses. A double layer of a HPMC-nitrate based film had a thickness of nearly 1 micron.

### Solution Development

The low solubility of barium nitrate limited the concentration of the solution. The solubility of Y(NO₃)₃.6H₂O in water is 134.7 g/100 g H₂O at 22° C., Ho(NO₃)₃.5H₂O solubility in water is over 100 g/100 g H₂O at room temperature, Ba(NO₃)₂ solubility is 10.5 g/100 g H₂O, and Cu(NO₃)₂.3H₂O solubility is 137.8 g/100 g H₂O (7). Other solvents were considered, including acetone, MEK, DMF, and propionic acid, but the nitrates were most soluble in water. Solution viscosity and ionic concentration both contribute to the thickness of the film, so the solvent must dissolve all of the nitrates and additives. PVA, HEC, MC, HPMC, PEG, and sucrose all dissolved easily in water, some under slight heating. Water is therefore a suitable solvent for this process, and has the benefits of being inexpensive and non-toxic. The solubility of precursor components in other solvents, combinations of solvents, and water at other pH values will be the subject of future research.

The cation stoichiometries of the non-fluorine solutions were targeted to be RE:Ba:Cu=1.03:1.86:3.10. The measured stoichiometries were 1.02(0.006):1.85(0.0017):3.13(0.020). Film stoichiometry will be optimized in future research. Preliminary studies indicated that films made from 1.03:1.86:3.10 stoichiometry solution performed better than films from 1:2:3 (stoichiometric) solutions. The former consistently produced films with J_{c}>1 MA/cm², while the latter produced maximum J_{c} of only 0.03 MA/cm². This suggested that off-stoichiometry solutions are needed in order to produce high-J_{c} films from this process, much like the TMAP process (9, 17, 18). High performance films, especially high in-field performance films, have been made with other stoichiometries in the TFA-MOD process (16).

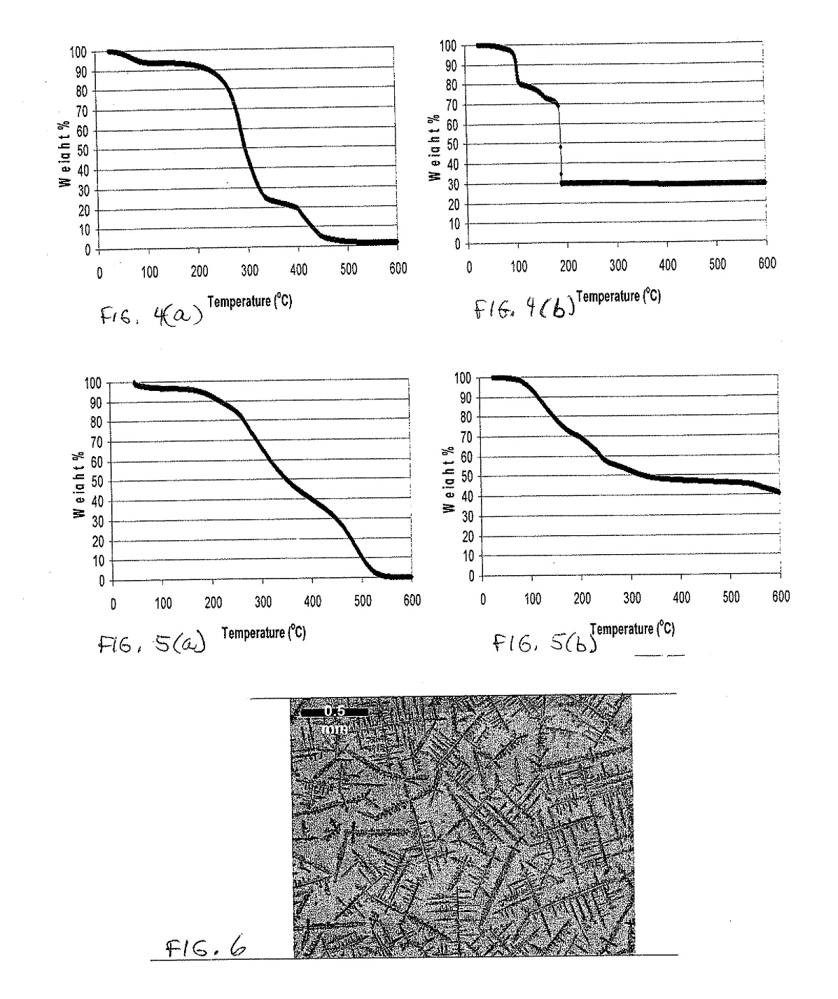

TGA data was compared to film performance to identify the decomposition characteristics of polymers that can be used in this process. The solutions that produced current-carrying films were those that contained PVA, HEC, HPMC, or MC. Solutions containing PAA did not produce current-carrying films, but XRD revealed oriented YBCO. Solutions containing PEG as a viscosity modifier and those using solvents other than water did not produce current-carrying films, and no YBCO was detected in XRD. FIGS. 3 through 5 show the TGA profiles for selected polymer powders and for the dried polymer-nitrate solutions.

The TGA results indicate that a wide decomposition range in temperature (>200° C.) is necessary to produce oriented YBCO films. This is a necessary, but not sufficient, requirement for selecting a polymer in this process. PMMA, for instance, decomposes over a wide range but was insufficiently soluble to make a viscous enough solution with any solvent tested. PAA decomposes properly, but partially dewets the substrate resulting in textured, but discontinuous, films. The TGA for the MC-nitrate solution suggested that rapid decomposition occurs very close to 200° C., so the heat treatment may be modified (e.g., slower ramp rate around that temperature) to obtain higher performance MC-nitrate films. The table below summarizes the different polymers tried, and their corresponding results.

TABLE 1
Selected viscosity modifiers and resulting polymer-nitrate films

| Polymer | Weight % | Solvent | Thickness | Highest J_{c} | Remarks |
|---|---|---|---|---|---|
| PVA | 5-10% | water | <100 to 250 nm | 3.73 MA/cm² | Best performing polymer so far, |
| | | | | | but limitations in thickness. |
| HEC | 0.6-1.8% | water | <100 to 800 nm | 0.73 MA/cm² | Performance not yet as high, but |
| | | | | | promising thickness possibilities |
| HPMC | 0.6-1.8% | water | <100 to 600 nm | 1.02 MA/cm² | Requires more total additive |
| | | | | | content (low solubility at elevated |
| | | | | | temperature). |
| MC | 2-10% | water | <100 to 350 nm | 2.3 MA/cm² | Purity problems with available |
| | | | | | grades. Cannot be used at elevated |
| | | | | | temperatures |
| PAA | 1-2% | water | | 0 MA/cm² | Problem with localized de-wetting; |
| | | | | | patchy film |

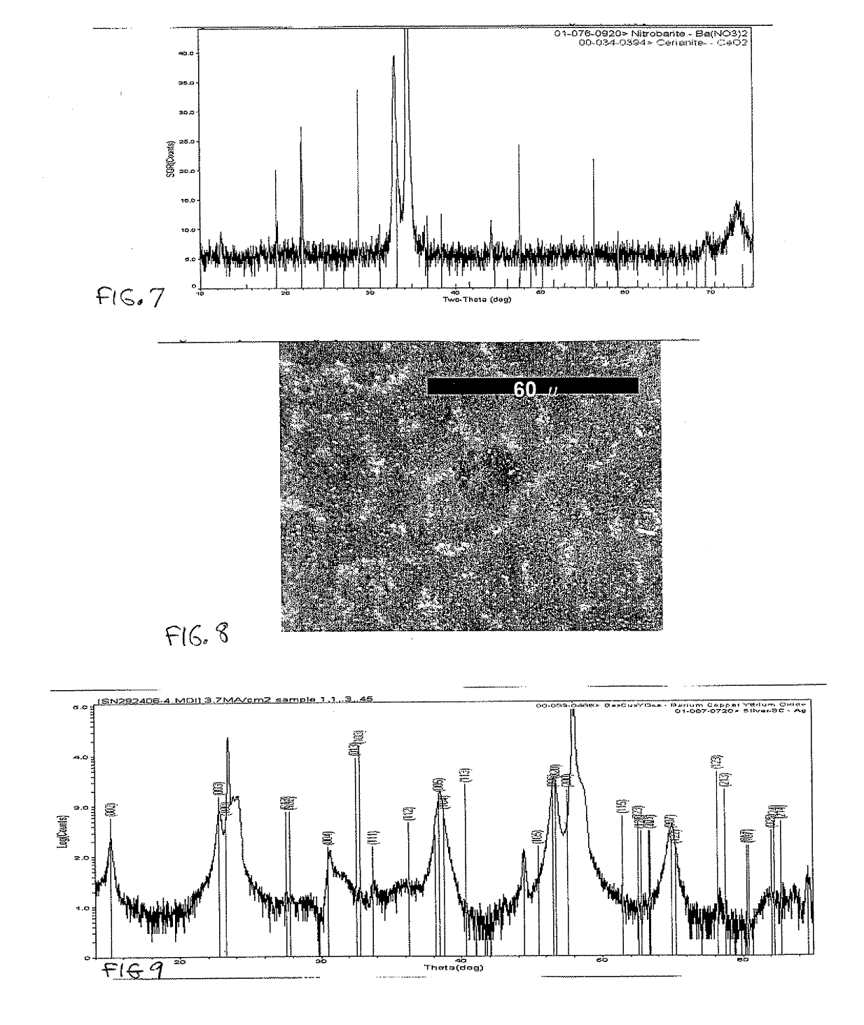

Large, dendritic structures (FIG. 6) were observed in a number of films immediately following coating of films from solutions that do not contain enough crystallization inhibitors. X-ray diffraction (FIG. 7) indicated the presence of Ba(NO₃)₂. The low solubility of Ba(NO₃)₂ means the solution becomes supersaturated after only a small amount of solvent has evaporated. The dendritic structure indicates rapid growth of nuclei into this supersaturated solution. Several factors can contribute to Ba(NO₃)₂ crystallization during spin-coating: the polymer content, humidity (dew point) during spin-coating, substrate surface roughness, and presence of a crystallization inhibitor.

The ambient dew point during spin-coating resulted in crystallization within the films and affected the critical current density of the final film. The figures below show optical micrographs of films spin-coated with the same PVA-nitrate solution under different humidity conditions. Higher dew points generally increased the number and size of segregation features.

The roughness of the substrate surface also affected Ba(NO₃)₂ crystallization during coating. Optical microscope observations made after spin-coating showed that there are more segregation features on films spin-coated on CeO₂-capped YSZ and LAO than on single-crystal YSZ substrates. Rougher substrates provide more nucleation sites for the Ba(NO₃)₂. CeO₂-capped YSZ substrates are generally smoother than LAO substrates, but defects in the solution-deposited ceria cap promote Ba(NO₃)₂ nucleation.

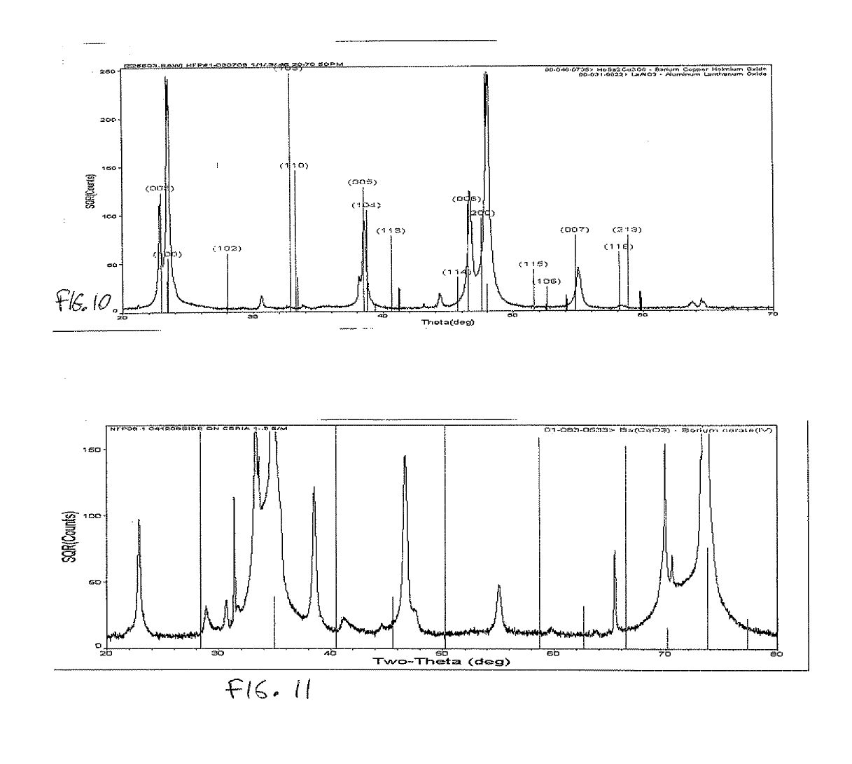

The use of crystallization inhibitors such as PEG can stop the crystallization of Ba(NO₃)₂ regardless of ambient conditions. Large amounts (˜30wt %) of PEG are required to stop segregation completely after coating under ambient temperatures and humidity. Coating under dry conditions (nitrogen box) and with the solution at elevated temperature lowers the amount of PEG necessary to produce homogenous films. Higher concentration solutions are therefore possible at elevated temperature and with crystallization inhibitors. The addition of PEG also helps prevent delamination of the film. Solutions with only PEG as the crystallization inhibitor segregate during firing in the range 125-200° C. The addition of sucrose stops this segregation. Solutions typically contained equal amounts of PEG and sucrose. FIG. 8 shows an uncracked film without any crystallization or segregation features, made from a solution kept at an elevated temperature and with sufficient amounts of crystallization inhibitors.

### Firing Studies

High-J_{c} films were obtained on LAO substrates with nitrate-based BYC and HBC solutions. The XRD results shown in FIGS. 9 and 10 clearly show c-axis orientation of YBCO and HoBCO films made using the polymer-nitrate processes. Very little, if any, off-axis and a-axis peaks were indicated.

Changing the ramp rate during the decomposition segment between the practical limits of 2° C./min and 10° C./min did not affect the performance of the films. The best YBCO and HoBCO films were produced in an all-dry process. More experiments need to be done in order to determine the effect of introducing water vapor at various points of the heat treatment on the final film performance.

Hot stage experiments on PVA-nitrate films under dry air showed bubbling around 130° C., and delamination around 200-210° C. Full heat treatments on HPMC-nitrate films with high total additive content also yielded delaminated films. High polymer contents resulted in tough films, and as the films lose elasticity during the early stages of heat-treatment, the resulting strains are relieved through delamination. The PVA-nitrate films appeared to begin delaminating at the edges of bubbles that appear at lower temperature. These bubbles may be caused by chemically unbound waters of hydration that are mechanically trapped by the polymer film. Water may act as a plasticizer for PVA, so water additions during the initial ramping stage of firing may reduce cracking Additives such as PEG also act to keep the film soft in the decomposition range of PVA and improve chemical transport rates through the film. Further investigation will be done on the role of water vapor in the solution and film during the early stages of heat treatment.

Films exposed to water vapor at the annealing temperature did not carry current. Water vapor may react with the film or release nitrous oxides and form HNO₃, damaging the film in the process. If water vapor is used during the decomposition segment, it is necessary to switch from moist 100 ppm O₂ gas to dry 100 ppm O₂ sometime before the high-temperature annealing segment. PVA-nitrate films that were heat-treated with some water vapor present performed better when the moist to dry gas switch was made before 200° C., although the optimum temperature for the gas switch depended on the dew point.

Cracking was observed in various polymer-nitrate based films with high total additive content. Cracking occurs when the film undergoes a large strain with insufficient elasticity to avoid reaching its yield stress. Large strains occur during decomposition of the polymer and the subsequent removal of a large amount of carbon from the film. Several different approaches may be taken to resolve the cracking problem, including the use of slower ramp rates to slowly remove carbon from the film and the reduction of the amount of carbon load in the green film. Solutions such as the elevated-temperature variant of HEC-nitrate have far-reduced carbon content and show no cracking in the final film.

Progress is being made on adapting the polymer-nitrate process to industry. All high performance films to date have been made on single crystal LAO. CeO₂-capped single-crystal YSZ substrates mimic RABiTs substrates commonly used in industry. A film formed on this substrate had a promisingly high J_{c} value of 0.25 MA/cm². The film reacted with the substrate, forming BaCeO₃ as seen in the x-ray diffraction pattern shown in FIG. 11. Future work will optimize processing at lower temperatures which will reduce the extent of this reaction and improve J_{c}. Research also continues into ways of improving thickness through solution or deposition modification. Overall, the polymer-nitrate process shows a great deal of promise for industrial application.

High-J_{c} ReBCO films were successfully produced using nitrate-water-additive solutions according to the invention. Films made from 1.03:1.86:3.10 stoichiometry solutions had J_{c} values over 1 MA/cm². Viscosity modifiers were found to significantly adjust the viscosity and green thickness of the film, leading to some increase in final thickness for films based on some solutions. Crystallization inhibitor additions were found to eliminate Ba(NO₃)₂ crystallization, and some may also help reduce delamination of films made from solutions with high total polymer content. Crystallization was also reduced by having lower humidity during coating and coating on smoother substrates. Water vapor was found to be detrimental, especially at higher temperatures. More experiments will be done to explore the role of water vapor during heat treatment, as well as the optimum processing conditions to obtain high-J_{c} films on other substrates such as CeO₂-capped YSZ.

The films made according to the invention had single-coat thicknesses of 0.10-0.80 microns, and J_{c} values greater than 1 MA/cm². The nitrate process disclosed herein presents several advantages. The precursor solution is relatively simple to make and does not require the fabrication of intermediate substances. Similarly, the heat treatment is a single step and quite short compared to TFA-based processes, and has none of the problematic fluorine. A single coat can yield a film with 100-800 nm thickness, and it is possible to build up thickness by adjusting the amount of viscosity modifier and crystallization inhibitors in the solution and/or spin-coating multiple layers on the same substrate. Compared to previous work done with nitrates, the process disclosed herein can produce high J_{c} films with similar and higher thickness (˜250 nm, up to ˜800 nm for a single layer), and have the advantage of using an environmentally friendly solvent (water) as a solvent with shorter heat treatment times. These advantages may make nitrate-MOD an appealing alternative to TFA-MOD for industrial-scale coated conductor production.

### REFERENCES

1. Apetrii, C., H. Schlorb, M. Falter, I. Lampe, L. Schultz, D. Holzapfel: YBCO thin films prepared by fluorine-free polymer-based chemical solution deposition. IEEE Trans. Appl. Supercond., 15, 2642-2644 (2005).
2. Christen, H. M., D. F. Lee, F. A. List, S. W. Cook, K. J. Leonard, L. Heatherly, P. M. Martin, M. Paranthaman, A. Goyal and C. M. Rouleau: Pulsed electron deposition of fluorine-based precursors for YBa2Cu3O7-x-coated conductors. Supercond. Sci. Technol., 18, 1168-1175 (2005).
3. Goto, T. and I. Horiba: A method for producing high-T_{c} Y—Ba—Cu—O superconducting filaments by die-free spinning Japanese Jour. Appl. Phys., 26(12), L-1970-L-1972 (1987).
4. Gupta, A., G. Koren, E. A. Giess, N. R. Moore, E. J. M. O'Sullivan, E.I. Cooper: Y₁Ba₂Cu₃I_{7-δ} thin films grown by a simple spray deposition technique. Appl. Phys. Lett., 52(2), 163-165 (1988).
5. Ng, M. F., and M. J. Cima: Heteroepitaxial growth of lanthanum aluminate films derived from mixed metal nitrates. J. Mater. Res., 12, 1306-1314 (1997).
6. Paranthaman, M. and T. Izumi: High-performance YBCO-coated superconductor wires. Mater. Res. Soc. Bul., 533-541 (2004).
7. Patnaik, P: Handbook of Inorganic Chemicals. (2003).
8. Schoop, U., M. W. Rupich, C. Thieme, D. T. Verebelyi, W. Zhang, X. Li, T. Kodenkandath, N. Nguyen, E. Siegal, L. Civale, T. Holesinger, B. Maiorov, A. Goyal, and M. Paranthaman: Second Generation HTS wire based on RABiTS substrates and MOD YBCO. IEEE Trans. App. Supercond., 15 (2), 2611-2616 (2005).
9. Shi, D., Y. Xu, H. Yao, J. Lian, L. Wang, A. Li, and S. X. Dou: The development of YBa₂Cu₃Oₓ thin films using a fluorine-free sol-gel approach for coated conductors. Supercond. Sci. Technol. 17 1420-1425 (2004).
10. Stewart, E., M. S. Bhuiyan, S. Sathyamurthy, and M. Paranthaman: Studies of solution deposited cerium oxide thin films on textured Ni-alloy substrates for YBCO superconductor. Materials Research Bulletin 41 1063-1068 (2006).
11. Supardi, Z., Supardi, G. Delabouglise, C. Peroz, A. Sin, C. Villard, P. Odier, F. Weiss: Epitaxial thick film of YBCO by high temperature spray pyrolysis for coated conductors. Physica C, 386, 296-299 (2003).
12. Tsukada, K., M. Furuse, M. Sohma, T. Manabe, I. Yamaguchi, W. Kondo, S. Fuchino, T. Kumagai: Preparation of high-Jc YBa2Cu3O7-y films on CeO2-buffered yttria-stabilized zirconia substrates by fluorine-free metalorganic deposition. Jpn. J. App. Phys., 44 (7A), 4914-4918 (2005).
13. Wang, S. S., Z. Han, H. Schmidt, H. W. Neumuller, P. Du, L. Wang, and S. Chen: Chemical solution growth of CeO2 buffer and YBCO layers on IBAD-YSZ/Hastelloy templates. Supercond. Sci. Technol., 18, 1468-1472 (2005).
14. Wesolowski, D. E., and M. J. Cima: Nitrate-based metalorganic deposition of CeO₂ on yttrium-stabilized zirconium. J. Mater. Res., Vol. 21, No. 1, January 2006.
15. Wypych, G: Plasticizers use and selection for specific polymers. ChemTec Laboratories, Inc., Publishing, Toronto, Canada (2001).
16. Xu, Y., A. Goyal, N. A. Rutter, S. Shi, M. Paranthaman, S. Sathyamurthy, P. M. Martin, and D. M. Kroeger: Fabrication of high critical current density YBa₂Cu₃O_{7-δ} films using a fluorine-free sol gel approach. J. Mater. Res. 18 (3) 677 (2003).
17. Xu, Y., A. Goyal, J. Lian, A. Rutter, S. Shi, S. Sathymurthy, M. Paranthaman, L. Wang, P. M. Martin, and D. M. Kroeger: Preparation of YBCO films on CeO₂-buffered (001) YSZ substrates by a non-fluorine MOD method. J. Am. Ceram. Soc. 87 [9] 1669-1676 (2004).
18. Xu, Y., A. Goyal, K. Leonard, and P. Martin: High performance YBCO films by the hybrid of non-fluorine yttrium and copper salts with Ba-TFA. Physica C, 421, 67-72 (2005).
19. Lu, F., and E. Hellstrom: (Y₁₋ₓSmₓ)Ba₂Cu₃O_{7-δ} films on RABiTS templates by a fluorine-free MOD process. Poster presented at the Applied Superconductivity Conference, Seattle, August 2006.
20. Araki, T. and I. Hirabayashi: Review of a chemical approach to YBa₂Cu₃O₇₋ₓ-coated superconductors—metalorganic deposition using trifluoroacetates. Supercond. Sci. Technol., 16, R71-R94 (2003).
21. Jia, Q., T. M. McCleskey, A. K. Burrell, Y. Lin: Polymer-assisted deposition of films. United States Patent Application 20050043184 (2005).

What is claimed is:

1) Method for making superconducting films comprising:
dissolving nitrate precursor compounds containing cations of a superconductor in water to form a solution;
adding an additive (including, but not limited to, polymers) to the solution;
coating the solution on a substrate; and
heat treating the coating to form a superconducting film.

2) The method of claim 1 wherein the additive is a viscosity modifier.

3) The method of claim 1 wherein the additive is a crystallization inhibitor.

4) The method of claim 1 wherein the heat treatment includes decomposition and high-temperature annealing segments.

5) The method of claim 1 wherein the coating step comprises spin coating.

6) The method of claim 1 wherein the coating step comprises slot coating.

7) The method of claim 4 wherein the decomposition segment includes a temperature ramp to a temperature in the range of 100° C. to 650 ° C.

8) The method of claim 4 wherein the high-temperature annealing segment includes a temperature ramp to a temperature in the range of 725° C. to 820° C.

9) The method of claim 1 or claim 2 wherein the viscosity modifier is PVA.

10) The method of claim 1 or claim 2 wherein the viscosity modifier is MC or its derivatives.

11) The method of claim 1 or claim 2 wherein the viscosity modifier is HEC.

12) The method of claim 1 or claim 3 wherein the crystallization inhibitor is PEG.

13) The method of claim 1 or claim 3 wherein the crystallization inhibitor is sucrose.

14) The method of claim 1 wherein the superconductor is ReBCO.

15) The method of claim 14 wherein the superconductor is YBCO.

16) The method of claim 14 wherein the superconductor is HoBCO.

17) The method of claim 14 wherein the stoichiometry of the ReBCO is approximately 1:1.8:3.

18) The method of claim 1 wherein the substrate is a single crystal.

19) The method of claim 18 wherein the single crystal is LaAlO₃ (LAO).

20) The method of claim 18 wherein the substrate is a buffered metal substrate.

21) The method of claim 4 wherein water vapor is present during heat treatment.

22) Method for making a superconducting ReBCO film comprising:
dissolving nitrate precursor compounds containing Re, Ba, and Cu cations in water to make a solution;
adding a viscosity modifier and crystallization inhibitors to the solution;
coating the solution on a substrate;
decomposing the nitrate compounds in the coating in a first heat treatment segment; and
annealing the coating in a high-temperature environment to form the superconducting film.

23) The method of claim 22 wherein the viscosity modifier is PVA and the crystallization inhibitor is PEG.

24) The method of claim 22 wherein the viscosity modifier is HEC and the crystallization inhibitors are PEG and sucrose.

25) The method of claim 22 wherein the substrate is a single crystal.

26) Polymer-nitrate solution comprising;
nitrate compounds including ReBa and Cu cations;
a viscosity modifier; and crystallization inhibitors all dissolved in water.
